(19) United States
(12) Patent Application Publication
(10) Pub. No.: US 2009/0032094 A1
(43) Pub. Date: Feb. 5, 2009

(54) SOLAR CELL AND METHOD OF FABRICATING THE SAME

(75) Inventor: Satoshi Aoki, Tochigi (JP)

Correspondence Address: ARENT FOX LLP, 1050 CONNECTICUT AVENUE, N.W., SUITE 400, WASHINGTON, DC, 20036, US

(73) Assignee: Honda Motor Co., Ltd, Tokyo (JP)

(21) Appl. No.: 12/162,260

(22) PCT Filed: Jan. 26, 2007
(86) PCT No.: PCT/JP2007/051303

§ 371 Date: Jul. 25, 2008

(30) Foreign Application Priority Data
Jan. 30, 2006 (JP) 2006-011924

(51) Int. Cl. H01L 31/00; B32B 37/02

(52) U.S. Cl. 136/256; 156/272.8

(57) ABSTRACT

A light absorbing layer 3 and a buffer layer 4 are divided by removing the light absorbing layer and the buffer layer by a laser, a metal needle or the like, successively, laser anneal working is carried out by thermally melting an end portion by irradiating a laser to include the divided end portion to constitute the end portion which has been substantially vertical in an inclined shape. Thereby, a thickness of TCO laminated on the inclined end portion is substantially equal to a thickness of TCO formed at an upper face of the light absorbing layer.

### TECHNICAL FIELD

The present invention relates to a solar cell having an inner series connecting structure and a method of fabricating the same.

### RELATED ART

A solar cell for receiving light and converting light into an electric energy is classified to a bulk group and a thin film group by a thickness of a semiconductor.

Among them, the thin film group is a solar cell having a thickness of a semiconductor layer of several tens μm through several μm or smaller and is classified into a Si thin film group and a compound thin film group. There are kinds of a II-VI group compound group, a chalcopyrite group and the like in the compound thin film group and a number thereof has been commercialized.

Among them, a chalcopyrite type solar cell belonging to the chalcopyrite group is referred to as another name of a CIGS (Cu(InGa)Se) group thin film solar cell or a CIGS solar cell or I-III-VI group in view of a substance used. The chalcopyrite solar cell is a solar cell of forming a light absorbing layer by a chalcopyrite compound and is characterized in a high efficiency, without optical deterioration (aging change), excellent in radiation resistance, having a wide light absorbing wavelength region, having a high light absorption coefficient and the like and currently, a research for mass production has been carried out.

FIG. 1 shows a sectional structure of a general solar cell having an inner series connecting structure by taking an example of a chalcopyrite type solar cell.

As shown by FIG. 1, a chalcopyrite type solar cell is formed by a lower electrode layer (Mo electrode layer) formed on a substrate of glass or the like, a light absorbing layer (CIGS light absorbing layer) including copper, indium, gallium, selenium, a buffer layer thin film having a high resistance formed by InS, ZnS, CdS or the like on the light absorbing layer thin film, and an upper electrode thin film (TCO) formed by ZnoAl or the like. Further, when soda-lime glass is used for the substrate, there is also a case of providing an alkali control layer whose major component is SiO₂ or the like with an object of controlling an amount of invasion of an alkali metal component from inside of the substrate to the light absorbing layer.

When light of solar ray or the like is irradiated to the chalcopyrite type solar cell, a pair of electron (−) and hole (+) is generated, according to the electron (−) and the hole (+), at a junction face of P type and N type semiconductors, the electron (−) is gathered to N type and the hole (+) is gathered to P type, as a result, an electromotive force is generated between the N type and the P type. A current can be outputted by connecting a conductor to the electrodes under the state.

Steps of fabricating a chalcopyrite type solar cell will be explained in reference to FIG. 2.

First, an Mo (molybdenum) electrode constituting a lower electrode is formed at a substrate of soda-lime glass or the like by sputtering or the like.

Next, the Mo electrode is divided by removing the Mo electrode by irradiating a laser or the like (first scribe, FIG. 2 (a)).

After the first scribe, a machined chip is cleaned by water or the lie, copper (Cu), indium (In), gallium (Ga) are adhered thereto by sputtering, vapor deposition or the like to form a layer referred to as a precursor. By putting the precursor into a furnace to anneal at a temperature of 400° C. through 600° C. in an atmosphere of H₂Se gas, a light absorbing layer thin film of P type is provided. The annealing step is normally referred to as a gas phase selenidation or, simply selenidation.

Next, a buffer layer of n type of CdS, ZnO, InS or the like is laminated onto a light absorbing layer. The buffer layer is formed by a dry process of sputtering or the like or a wet process of CBD (chemical bath deposition) or the like as a general process. Next, the buffer layer and the precursor are divided by removing the buffer layer and the precursor by laser irradiation, a metal needle or the like (second scribe, FIG. 2 (b)).

Thereafter, a transparent electrode (TCO: Transparent Conducting Oxides) film of ZnOAl or the like is formed by sputtering or the like as an upper electrode (FIG. 2 (c)).

Finally, TCO, the buffer layer and the precursor are divided by removing TCO, the buffer layer and the precursor by laser irradiation, a metal needle or the like (third scribe, FIG. 2 (d)) to provide the CIGS thin film solar cell.

The solar cell provided here is referred to as cell constituted by connecting unit cells each comprising the divided lower electrode and the divided light absorbing layer and the divided upper electrode monolithically and in series by way of contact electrode portions, when actually used, a single or a plurality of the cells are packaged and worked as a module (panel).

According to the cell, a plurality of series stages are monolithically divided by isolating elements by the respective scribe steps, and by changing a number of the series steps (number of unit cells), a voltage of the cell can be designed to change arbitrarily. The point constitutes one of advantages of the thin film solar cell.

According to the chalcopyrite type solar cell of the background art, as described above, mechanical scribe and laser scribe are used as technologies for carrying out the second scribe.

The mechanical scribe is a technology of mechanically carrying out scribe by moving a metal needle (needle) a front end of which is constituted by a taper shape while pressing the metal needle by a predetermined pressure. (refer to, for example, Patent Reference 1)

FIG. 3 shows a schematic view of carrying out the second scribe by mechanical scribe.

Further, the laser scribe is a technology of removing and dividing the light absorbing layer by irradiating a laser constituted by exciting Nd: YAG crystal by a continuous discharging lamp of an arc lamp or the like (Nd: YAG laser or the like) to the light absorbing layer. (refer to, for example, Patent Reference 2)

### Patent Reference 1: JP-A-2004-115356

### Patent Reference 2: JP-A-11-312815

### DISCLOSURE OF THE INVENTION

### Problems to be Solved by the Invention

The needle front end used in the case of the mechanical scribe is constituted by a converging shape as described above, and therefore, also the scribed side wall of the light absorbing layer is constituted by an inclined shape to some degree, however, an angle almost near to vertical is constituted. Therefore, TCO cannot be formed at the side wall by a thickness the same as that of an upper face. An example thereof will be explained in reference to FIG. 4.

FIG. 4 (a) is an SEM photograph of a section taking a state in which a portion of light absorbing layer is scribed by using the metal needle of a background art and TCO constituting an upper electrode is formed thereon by sputtering, and FIG. 4 (b) is a diagram simplifying to show the photograph of FIG. 4 (a). As is apparent from FIG. 4, TCO is formed on a side of a wall face of the light absorbing layer formed by the scribe more thinly than on a side of an upper face. Further, a crack is brought about at TCO at a vicinity of a contact point of a wall face side of the light absorbing layer and an upper portion side of an Mo electrode. When TCO is thin or cracked, an electric resistance at the portion is increased. Normally, the solar cell of the thin film group is formed with a number of unit cells monolithically on one sheet of a substrate in order to realize a high voltage by one sheet of a solar cell module, and when resistance values of portions of connecting the unit cells are increased, as a result, a conversion efficiency of the module is deteriorated.

Further, when the portions of connecting the unit cells are thinned, the portions are easy to be destructed by a force from outside or an aging change, which amounts to a reduction in a reliability.

Although when a thickness of a transparent upper electrode is thickened, a deficiency in the thickness of the portion of connecting the unit cells of the wall face side of the light absorbing layer or the like can be compensated for to some degree, the transparent upper electrode is not completely transparent, and therefore, an amount of light reaching the light absorbing layer is reduced, the power generation conversion efficiency is reduced, and it is not realistic to thicken the transparent upper electrode.

Further, according to the technology of carrying out the second scribe by using a laser, it is difficult to adjust a strength of the laser used inscribe, and therefore, there poses a problem that the lower electrode (Mo electrode) is destructed or a contact resistance of the upper transparent electrode and the lower Mo electrode is extremely deteriorated. For example, although when an output of the laser is intensified for removing the light absorbing layer, the light absorbing layer is firmly removed, an extraneous laser damages the Mo electrode constituting the lower electrode. Further, when the output of the laser is weakened, in this case, the light absorbing layer remains and the contact resistance is extremely deteriorated.

The laser scribe cannot be used in mass production steps since it is very difficult to strengthen or weaken the laser in this way, further, even when the strength of the laser is optimally adjusted, by a delicate change in a film thickness or the like of the light absorbing layer, an optimum value of the strength of the laser is changed.

### Means for Solving the Problems

In order to resolve the above-described problem, there is provided a method of fabricating a solar cell including the steps of:

a lower electrode layer forming step of forming a lower electrode layer on a side of an upper face of a substrate;

a first scribe step of dividing the lower electrode layer;

a light absorbing layer forming step of forming a light absorbing layer on the scribed lower electrode layer;

a second scribe step of dividing the light absorbing layer by a laser or a metal needle;

a laser anneal step of irradiating a laser to include an end portion of the light absorbing layer divided by the second scribe step;

a step of forming an upper electrode and a contact electrode portion by laminating a transparent conductor on the divided light absorbing layers and the lower electrode exposed therebetween; and

a third scribe step of dividing the upper electrode.

Although the method of fabricating the solar cell according to the invention includes the above-described respective steps as a basic constitution, a method including not only the steps but film forming steps of forming, for example, a buffer layer, an alkali interposed thereamong passivation film, a reflection preventing film and the like is included in the method of fabricating the solar cell of the invention.

Further, when the first scribe step is carried out by a laser, by making a frequency of a laser at the laser anneal step higher than a frequency of the laser of the first scribe step, an end portion of the light absorbing layer can be constituted by a gradual inclined face.

Further, there is provided a solar cell including:

a substrate;

a lower electrode layer divided into a plurality thereof to be formed on a side of an upper face of the substrate;

a light absorbing layer which is divided into a plurality thereof to be formed on the plurality of lower electrode layers and divided end portions of which are formed in an inclined shape by laser anneal;

a transparent upper electrode layer formed by being laminated on the light absorbing layer; and

a contact electrode portion formed at the inclined end portion of the divided light absorbing layer to electrically connect the upper electrode and the lower electrode.

A chalcopyrite compound is preferable as the light absorbing layer.

### ADVANTAGE OF THE INVENTION

By annealing the end portion of the light absorbing layer divided after scribing to divide the light absorbing layer by the laser, the transparent upper electrode (contact electrode portion) is not extremely thinned at the end portion of the light absorbing layer and is not cracked, an inner resistance value of series connection can be made to be low, as a result, the chalcopyrite type solar cell having a high photoelectric conversion efficiency can be provided

### BRIEF DESCRIPTION OF THE DRAWINGS

FIG. 1 is a sectional view showing a structure of a solar cell of a background art.

FIG. 2 illustrates views showing steps of fabricating the solar cell of the background art.

FIG. 3 is a view showing a behavior of scribe by a metal needle.

(a) is a SEM photograph of a section of the solar cell of the background art, and (b) is a diagram tracing the SEM photograph of (a) along boundaries of layers.

FIG. 5 is a sectional view of a solar cell according to the invention.

FIG. 6 is a view of explaining a method of fabricating the solar cell according to the invention.

FIG. 7

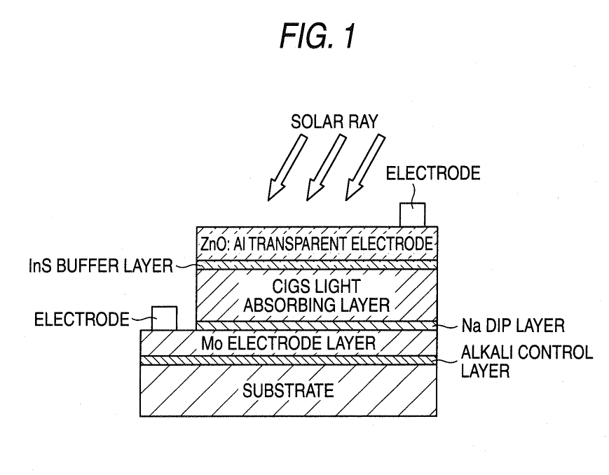

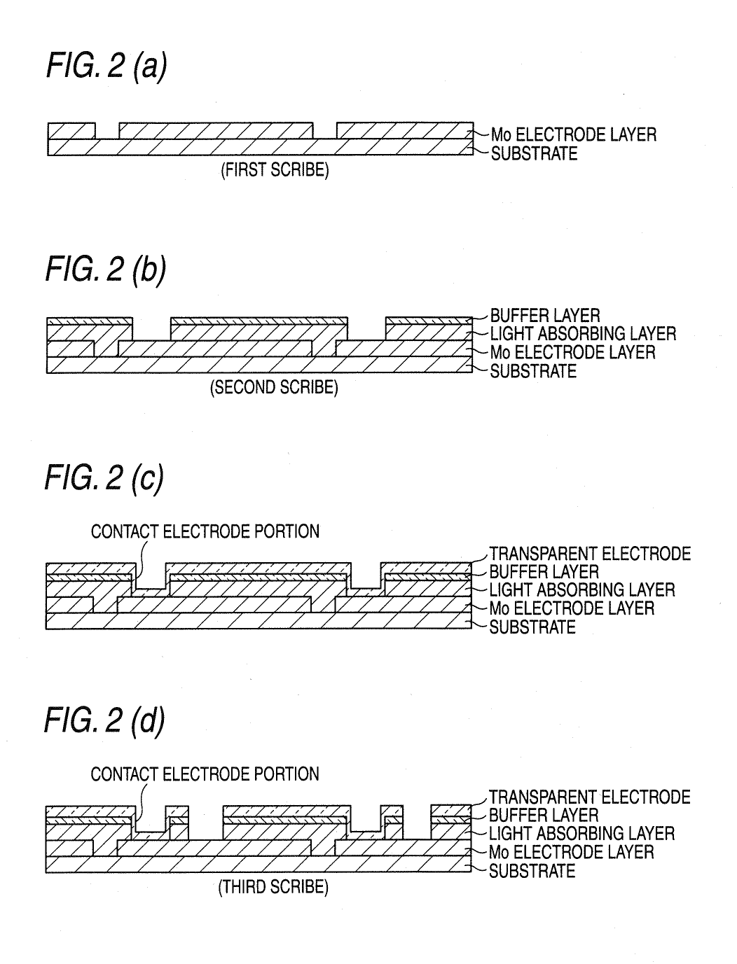

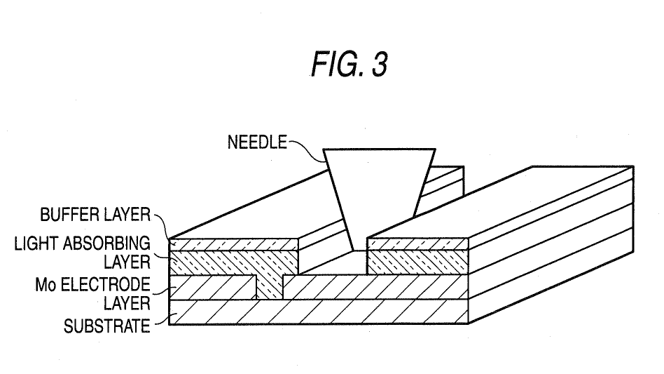

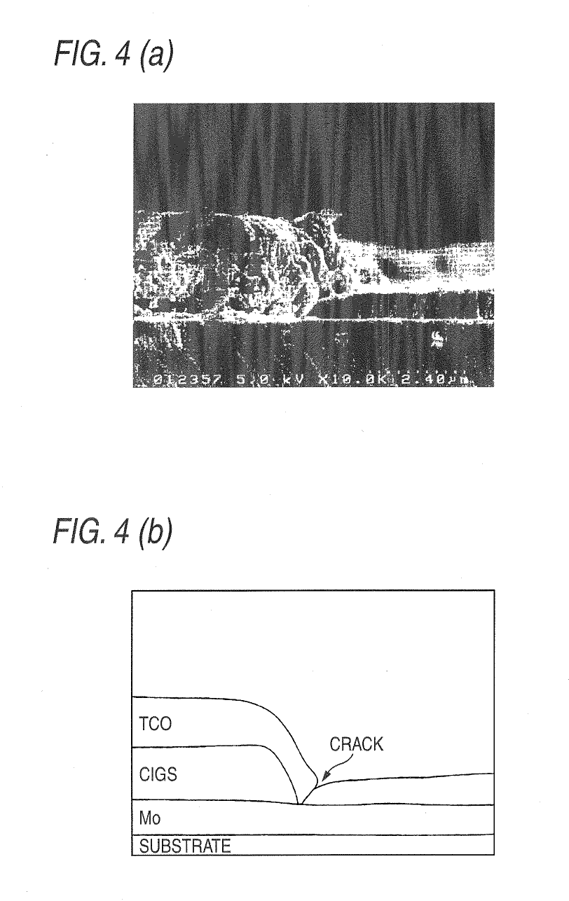

(a) is a SEM photograph of a section of the solar cell according the invention, and (b) is a diagram tracing the SEM photograph of (a) along boundaries of layers.

### DESCRIPTION OF REFERENCE NUMERALS AND SIGNS

1 . . . substrate
2 . . . lower electrode layer (Mo electrode layer)
3 . . . light absorbing layer thin film (CIGS light absorbing layer)
4 . . . buffer layer thin film
5 . . . upper transparent electrode layer (TCO)
6 . . . contact electrode portion

### BEST MODE FOR CARRYING OUT THE INVENTION

### Embodiment 1

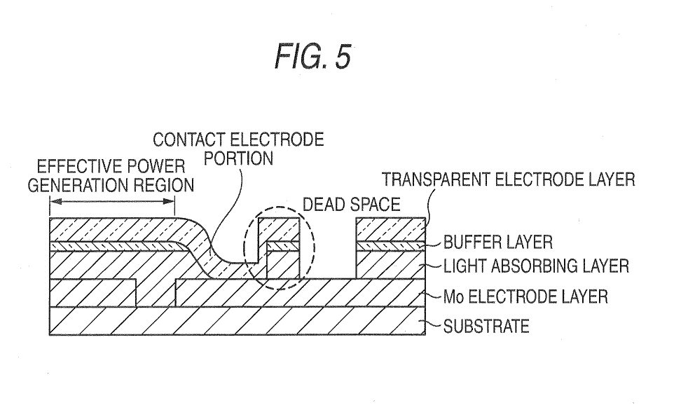

FIG. 5 shows a section of a chalcopyrite type solar cell according to the invention.

Portions the same as those of the background art are attached with the same notations.

The solar cell according to the invention is formed with a cell constituting one unit (here, referred to as ‘unit cell’ for convenience of explanation) from a lower electrode layer 2 (Mo electrode layer) formed on a substrate 1 of glass or the like, a light absorbing layer thin film 3 (CIGS light absorbing layer) including copper, indium, gallium, selenium, a buffer layer thin film 4 of a high resistance formed by InS, ZnS, CdS or the like on the light absorbing layer thin film 3, and an upper transparent electrode layer 5 (TCO) formed by ZnOAl or the like.

Contiguous unit cells are electrically connected by bringing the upper transparent electrode layer 5 of one unit cell into direct contact with the lower electrode layer 2 of other unit cell at a contact electrode portion 6 constituting a portion of the upper transparent electrode layer 5. According to the invention, the light absorbing layer 3 and the buffer layer 4 are worked by gradual inclined shapes at end portions of the layers, and therefore, the upper transparent electrode layer 5 reaches the lower electrode layer in a form of being deposited at an upper portion of the inclined shape.

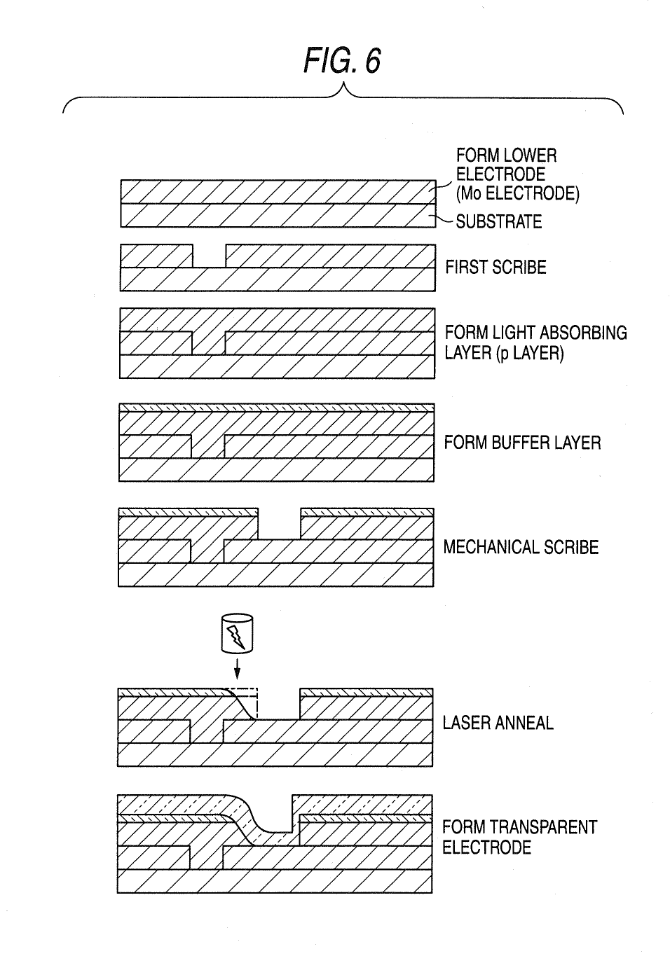

Next, FIG. 6 shows a method of fabricating the chalcopyrite type solar cell of the invention.

First, an Mo (molybdenum) electrode constituting the lower electrode 2 is formed on an upper face side of the substrate 1 by sputtering or the like. Titanium, tungsten or the like may be used for the lower electrode 2 other than molybdenum. Further, an alkali control layer constituted by SiO₂ or the like may be provided between the substrate and the lower electrode.

Next, the Mo electrode is divided by removing the Mo electrode by irradiating a laser or the like. (first scribe)

As a laser, an excimer laser having a wavelength of 248 nm, or a third harmonic of YAG laser having a wavelength of 355 nm or the like is preferable. Further, it is preferable to ensure a work width of laser by about 80 through 100 nm, thereby, insulation between the contiguous Mo electrodes can be ensured.

After the first scribe, copper (Cu), indium (In), gallium (Ga) are adhered by sputtering, vapor deposition or the like to form a layer referred to as precursor. The light absorbing layer thin film 3 is provided by putting the precursor into a furnace and annealing the precursor at a temperature of about 400° C. through 600° C. in an atmosphere of H₂Se gas. The annealing step is normally referred to as gas phase selenidation or simply selenidation.

A number of technologies have been developed in the step of forming the light absorbing layer thin film 3 such as a method of carrying out annealing after forming Cu, In, Ga, Se by vapor deposition. Although according to the embodiment, an explanation has been given by using gas phase selenidation, the step of forming the light absorbing layer is not limited in the invention.

Next, the buffer layer 4 constituting an n type semiconductor of CdS, ZnO, InS or the like is laminated on the light absorbing layer 3. The buffer layer 4 is formed by a dry process of sputtering or the like, or a wet process of CBD (chemical bath deposition) or the like as a general process. The buffer layer can also be omitted by improving a transparent electrode, mentioned later.

Next, the light absorbing layer 3 and the buffer layer 4 are divided by removing the light absorbing layer and the buffer layer by a laser or a metal needle. (second scribe)

End portions of the divided light absorbing layer 3 and the divided buffer layer 4 are constituted by shapes cut to be erected substantially vertically although the front end of the metal needle is constituted by the converging shape.

Next step carries out laser anneal working for the end portions which have been substantially vertical in an inclined shape by thermally melting the end portions by irradiating a laser to include the end portions. As the irradiating laser, a fourth harmonic of Nd:YVO₄ having a wavelength of 266 nm is used under a condition of a frequency of 40 kHz and an output of 230 mW. A kind of the laser is not particularly limited so far as the laser is a laser capable of carrying out thermal working and a laser of an energy (short wavelength) higher than a band gap energy of the light absorbing layer of an excimer laser or Nd: YAG or the like other than Nd:YVO₄ used in the invention. Also with regard to the frequency, although a continuous wide laser can be used, it is preferable to make the frequency higher than that of the laser used in the first scribe so as not to destruct the lower electrode layer.

Further, with regard to one end portion of the light absorbing layer produced by the second scribe, the region constitutes a so-to-speak dead space which does not contribute to effective power generation, and therefore, it is not necessary to carry out the laser anneal working therefor.

Thereafter, an upper transparent electrode (TCO) of ZnOAl or the like for constituting the upper electrode 5 is formed on the buffer layer 4 and the lower electrode 2 at which the second scribe is carried out by sputtering or the like. TCO is deposited also on the light absorbing layer 3 subjected to laser anneal working.

Finally, the division is carried out by removing TCO, the buffer layer and the precursor by laser irradiation, a metal needle or the like (element isolating scribe). By the element isolation, the solar cell of the inner series connecting structure shown in FIG. 5 is provided.

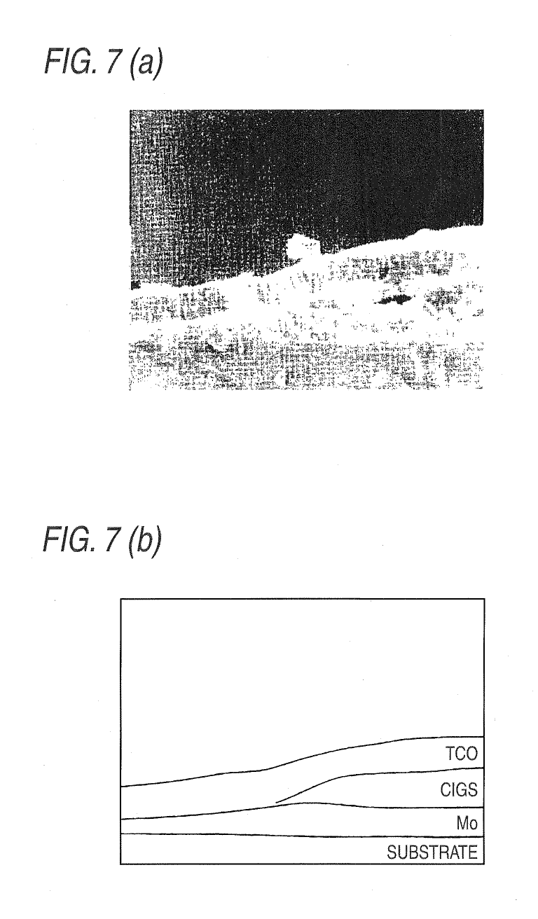

FIG. 7 (a) is a SEM photograph of a section of the chalcopyrite type solar cell formed by the embodiment, and (b) is a diagram simplifying to show the photograph of FIG. 7 (a).

Further, the buffer layer is formed to be very thin, and therefore, the buffer layer cannot be confirmed by the photograph. As shown by FIG. 7, the light absorbing layer and the buffer layer are worked in the inclined shape by laser annealing, and therefore, TCO deposited thereon is formed so as not to hardly change the thickness of the layer from the buffer layer to the lower electrode. A crack of TCO cannot be confirmed even in the photograph.

### INDUSTRIAL APPLICABILITY

In this way, according to the invention, the film thickness of the transparent electrode can be formed constant, further, a defect of a crack or the like is difficult to be brought about, and therefore, a resistance of the cell can be reduced, and the solar cell having the high power generation conversion efficiency can be provided.

Further, a region of carrying out the laser anneal working after the second scribe is a so-to-speak dead space which does not contribute to effective power generation, and therefore, a reduction in a power generation amount is not brought about by carrying out the laser anneal working.

Although the invention has been explained in details and in reference to specific embodiments, it is apparent for the skilled person that the invention can variously be changed or modified without deviating from the spirit and the range of the invention.

The application is based on Japanese Patent Application (Japanese Patent Application No. 2006-019924) filed on Jan. 30, 2006 and a content thereof is incorporated herein by reference.

1. A method of fabricating a solar cell comprising the steps of:
a lower electrode layer forming step of forming a lower electrode layer on a side of an upper face of a substrate;
a first scribe step of dividing the lower electrode layer;
a light absorbing layer forming step of forming a light absorbing layer on the scribed lower electrode layer;
a second scribe step of dividing the light absorbing layer by a laser or a metal needle;
a laser anneal step of irradiating a laser to include an end portion of the light absorbing layer divided by the second scribe step;
a step of forming an upper electrode and a contact electrode portion by laminating a transparent conductor on the divided light absorbing layers and the lower electrode exposed therebetween; and
a third scribe step of dividing the upper electrode.

2. The method of fabricating a chalcopyrite type solar cell according to claim 1, wherein
the first scribe step is a step of dividing the lower electrode layer by a laser, and
a frequency of a laser at the laser anneal step is higher than a frequency of the laser of the first scribe step.

3. A solar cell comprising:
a substrate;
a lower electrode layer divided into a plurality thereof to be formed on a side of an upper face of the substrate;
a light absorbing layer which is divided into a plurality thereof to be formed on the plurality of lower electrode layers and divided end portions of which are formed in an inclined shape by laser anneal;
a transparent upper electrode layer formed by being laminated on the light absorbing layer; and
a contact electrode portion formed at the inclined end portion of the divided light absorbing layer to electrically connect the upper electrode and the lower electrode.

4. The solar cell according to claim 3, wherein
the light absorbing layer is a chalcopyrite compound.
